(19) United States
(12) Patent Application Publication
(10) Pub. No.: US 2020/0303383 A1
(43) Pub. Date: Sep. 24, 2020

(54) SEMICONDUCTOR DEVICE

(71) Applicant: Toshiba Memory Corporation, Minato-ku (JP)

(72) Inventor: Takenori KODAMA, Yokkaichi (JP)

(73) Assignee: Toshiba Memory Corporation, Minato-ku (JP)

(21) Appl. No.: 16/566,261

(22) Filed: Sep. 10, 2019

(30) Foreign Application Priority Data
Mar. 20, 2019 (JP) 2019-053654

(51) Int. Cl. H01L 27/1157; H01L 23/522; H01L 23/528

(52) U.S. Cl. CPC H01L 27/1157; H01L 23/5283; H01L 23/5226

(57) ABSTRACT

According to one embodiment, a semiconductor device includes an N-type first well region; a P-type source diffusion layer and drain diffusion layer provided on a top surface of the first well region; a first gate insulating layer provided on the first well region between the P-type source diffusion layer and the P-type drain diffusion layer; a P-type first semiconductor layer provided on the first gate insulating layer; a second semiconductor layer provided on the first semiconductor layer via a first insulating layer; a P-type third semiconductor layer provided on the second semiconductor layer via a second insulating layer and including boron; and a first conductive layer provided on the third semiconductor layer via a third insulating layer.

### CROSS-REFERENCE TO RELATED APPLICATIONS

This application is based upon and claims the benefit of priority from prior Japanese Patent Application No. 2019-053654, filed Mar. 20, 2019, the entire contents of which are incorporated herein by reference.

### FIELD

Embodiments described herein relate generally to a semiconductor device.

### BACKGROUND

As a semiconductor device, a very low voltage transistor is known. The very low voltage transistor is a transistor intended for a high-speed operation. However, characteristics of the very low voltage transistor may deteriorate during the manufacture depending on the structure of the gate electrode.

### BRIEF DESCRIPTION OF THE DRAWINGS

FIG. 1 is a block diagram showing a configuration example of a semiconductor device according to an embodiment.

FIG. 2 is a circuit diagram showing a circuit configuration of a memory cell array included in the semiconductor device according to the embodiment.

FIG. 3 is a plan view showing an example of the planar layout of the memory cell array included in the semiconductor device according to the embodiment.

FIG. 4 is a cross-sectional view showing an example of the cross-section structure of the memory cell array included in the semiconductor device according to the embodiment.

FIG. 5 is a cross-sectional view showing an example of the cross-section structure of a memory pillar constituting part of the memory cell array included in the semiconductor device according to the embodiment.

FIG. 6 is a cross-sectional view showing an example of the cross-section structure of each of a PMOS transistor and NMOS transistor included in the semiconductor device according to the embodiment.

FIG. 7 is a flowchart showing an example of the method for manufacturing the semiconductor device according to the embodiment.

FIG. 8 is a cross-sectional view of PMOS transistor and NMOS transistor formation regions, which shows an example of a manufacturing step of the semiconductor device according to the embodiment.

FIG. 9 is a cross-sectional view of the PMOS transistor and NMOS transistor formation regions, which shows an example of a manufacturing step of the semiconductor device according to the embodiment.

FIG. 10 is a cross-sectional view of the PMOS transistor and NMOS transistor formation regions, which shows an example of a manufacturing step of the semiconductor device according to the embodiment.

FIG. 11 is a cross-sectional view of PMOS transistor and NMOS transistor formation regions, which shows an example of a manufacturing step of the semiconductor device according to the embodiment.

FIG. 12 is a cross-sectional of the PMOS transistor and NMOS transistor formation regions, which shows an example of a manufacturing step of the semiconductor device according to the embodiment.

FIG. 13 is a cross-sectional view of the PMOS transistor and NMOS transistor formation regions, which shows an example of a manufacturing step of the semiconductor device according to the embodiment.

FIG. 14 is a cross-sectional view of the PMOS transistor and NMOS transistor formation regions, which shows an example of a manufacturing step of the semiconductor device according to the embodiment.

FIG. 15 is a cross-sectional view of the PMOS transistor and NMOS transistor formation regions, which shows an example of a manufacturing step of the semiconductor device according to the embodiment.

FIG. 16 is a cross-sectional view of the PMOS transistor and NMOS transistor formation regions, which shows an example of a manufacturing step of the semiconductor device according to the embodiment.

FIG. 17 is a cross-sectional view of the PMOS transistor and NMOS transistor formation regions, which shows an example of a manufacturing step of the semiconductor device according to the embodiment.

FIG. 18 is a cross-sectional view of the PMOS transistor and NMOS transistor formation regions, which shows an advantage of the manufacturing method of the semiconductor device according to the embodiment.

FIG. 19 is a cross-sectional view of the PMOS transistor and NMOS transistor formation regions, which shows an example of a manufacturing step of the semiconductor device according to a comparative example of the embodiment.

FIG. 20 is a cross-sectional view of the PMOS transistor and NMOS transistor formation regions, which shows an example of a manufacturing step of the semiconductor device according to the comparative example of the embodiment.

FIG. 21 is a cross-sectional view of the PMOS transistor and NMOS transistor formation regions, which shows an example of a manufacturing step of the semiconductor device according to the comparative example of the embodiment.

FIG. 22 is a cross-sectional view of the PMOS transistor and NMOS transistor formation regions, which shows an advantage of the manufacturing method of the semiconductor device according to the embodiment.

### DETAILED DESCRIPTION

In generally, according to one embodiment, a semiconductor device includes an N-type first well region; a P-type source diffusion layer and drain diffusion layer provided on a top surface of the first well region; a first gate insulating layer provided on the first well region between the P-type source diffusion layer and the P-type drain diffusion layer; a P-type first semiconductor layer provided on the first gate insulating layer; a second semiconductor layer provided on the first semiconductor layer via a first insulating layer; a P-type third semiconductor layer provided on the second semiconductor layer via a second insulating layer and including boron; and a first conductive layer provided on the third semiconductor layer via a third insulating layer.

Hereinafter, an embodiment will be described with reference to the drawings. The embodiment describes, as an example, a device or method for embodying the technical idea of the invention. The drawings are schematic or conceptual, and the dimensions and ratios, etc. in the drawings are not always the same as the actual ones. The technical idea of the present invention is not specified by the shapes, configurations, arrangements, etc. of the structural elements.

In the following description, structural elements having substantially the same function and configuration will be assigned with the same reference symbol. A numeral following letters constituting a reference symbol is used for distinction between elements referred to by reference symbols including the same letters and having the same configuration. If elements represented by reference symbols including the same letters need not be distinguished, those elements are assigned with reference symbols including only the same letters.

### <1> Embodiment

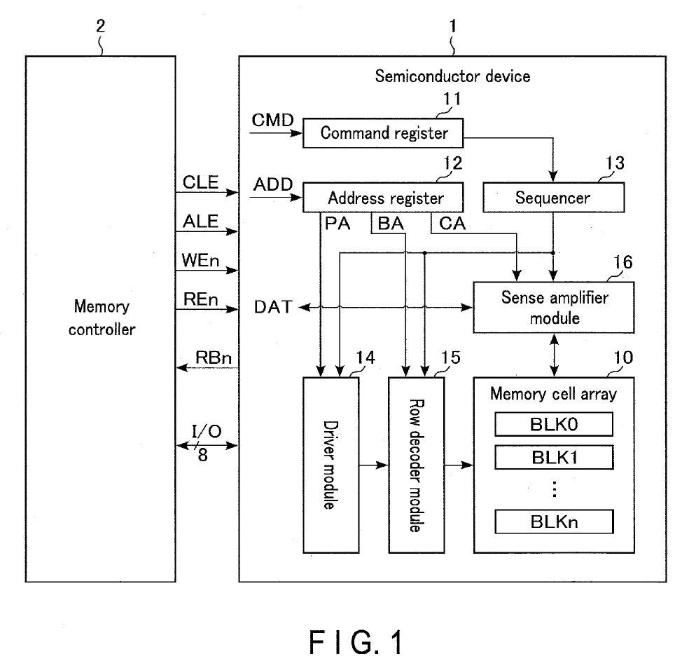

FIG. 1 shows a configuration example of a semiconductor device 1 according to an embodiment. Hereinafter, the semiconductor device 1 according to the embodiment will be described.

<1-1> Configuration of Semiconductor Device 1

<1-1-1> Overall Configuration of Semiconductor Device 1

The semiconductor device 1 is, for example, a NAND flash memory, which can nonvolatilely store data. The semiconductor device 1 is controlled by, for example, an external memory controller 2.

As shown in FIG. 1, the semiconductor device 1 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (where n is an integer not less than 1). The block BLK is a set of a plurality of memory cells that can nonvolatilely store data, and is used as, for example, a data erase unit.

A plurality of bit lines and a plurality of word lines are provided in the memory cell array 10. Each memory cell is associated with, for example, one bit line and one word line. A detailed configuration of the memory cell array 10 will be described later.

The command register 11 retains a command CMD received by the semiconductor device 1 from the memory controller 2. The command CMD includes an instruction to instruct, for example, the sequencer 13 to perform a read operation, a write operation, an erase operation, or the like.

The address register 12 retains address information ADD received by the semiconductor device 1 from the memory controller 2. The address information ADD includes, for example, a block address BA, a page address PA, and a column address CA. For example, the block address BA, page address PA, and column address CA are used to select a block BLK, word line, and bit line, respectively.

The sequencer 13 controls the operation of the entire semiconductor device 1. For example, the sequencer 13 controls the driver module 14, the row decoder module 15, and the sense amplifier module 16, etc. based on the command CMD retained in the command register 11 to execute a read operation, a write operation, an erase operation, and the like.

The driver module 14 generates voltages used in a read operation, a write operation, an erase operation, and the like. Then, the driver module 14 applies a generated voltage to a signal line corresponding to a selected word line based on, for example, the page address PA retained in the address register 12.

Based on the block address BA retained in the address register 12, the row decoder module 15 selects one corresponding block BLK in the memory cell array 10. Then, the row decoder module 15 transfers, for example, the voltage applied to the signal line corresponding to the selected word line to the selected word line in the selected block BLK.

In a write operation, the sense amplifier module 16 applies a desired voltage to each bit line in accordance with write data DAT received from the memory controller 2. In a read operation, the sense amplifier module 16 determines data stored in a memory cell based on the voltage of the corresponding bit line, and transfers the determination result to the memory controller 2 as read data DAT.

Communication between the semiconductor device 1 and the memory controller 2 is based on, for example, the NAND interface standard. For example, for the communication between the semiconductor device 1 and the memory controller 2, a command latch enable signal CLE, an address latch enable signal ALE, a write enable signal WEn, a read enable signal REn, a ready/busy signal REn, and an input/output signal I/O are used.

The command latch enable signal CLE is a signal that indicates that the input/output signal I/O received by the semiconductor device 1 is a command CMD. The address latch enable signal ALE is a signal that indicates that the input/output signal I/O received by the semiconductor device 1 is address information ADD. The write enable signal WEn is a signal that instructs the semiconductor device 1 to input therein an input/output signal I/O. The read enable signal REn is a signal that instructs the semiconductor device 1 to output therefrom an input/output signal I/O.

The ready/busy signal RBn is a signal that notifies the memory controller 2 of whether the semiconductor device 1 is in a ready state in which the semiconductor device 1 accepts an instruction from the memory controller 2 or in a busy state in which the semiconductor device 1 does not accept the instruction. The input/output signal I/O is, for example, an 8-bit signal, and may include, for example, a command CMD, address information ADD, and data DAT.

The above-described semiconductor device 1 and memory controller 2 may constitute a single semiconductor device in combination. Such a semiconductor device includes, for example, a memory card, such as an SD™ card, and a solid state drive (SSD).

<1-1-2> Circuit Configuration of Memory Cell Array 10

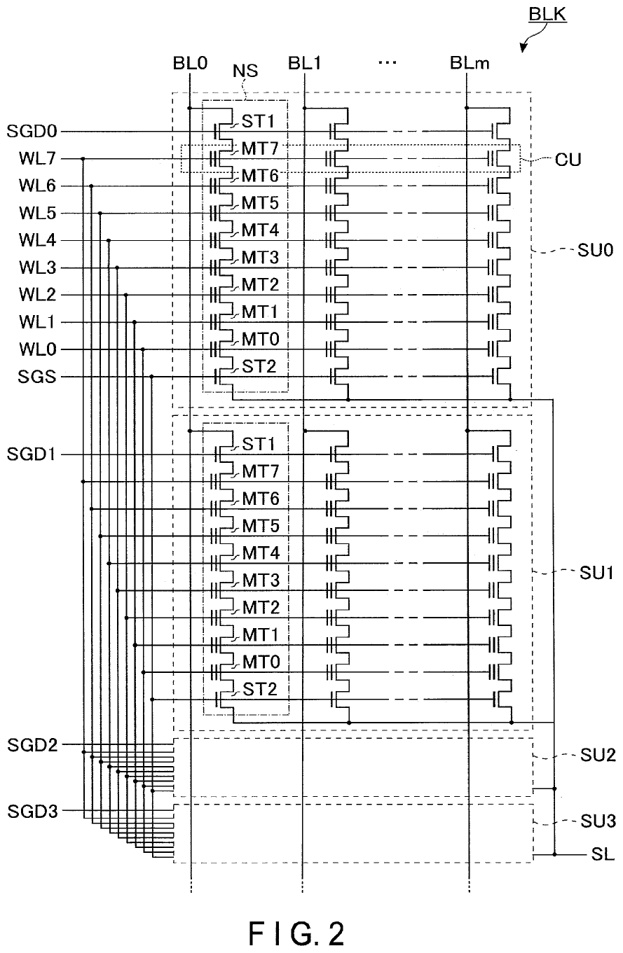

FIG. 2 shows one of a plurality of blocks BLK included in the memory cell array 10 as an example of the circuit configuration of the memory cell array 10 included in the semiconductor device 1 according to the embodiment.

As shown in FIG. 2, the block BLK includes, for example, four string units SU0 to SU3. Each string unit SU includes a plurality of NAND strings NS.

The NAND strings NS are associated with respective bit lines BL0 to BLm (m is an integer not less than 1). Each NAND string NS includes, for example, memory cell transistors MT0 to MT7 and select transistors ST1 and ST2.

Each memory cell transistor MT includes a control gate and a charge storage layer, and nonvolatilely retains data. The select transistors ST1 and ST2 are each used to select a string unit SU in various operations.

The drain of select transistor ST1 of each NAND string NS is coupled to an associated bit line BL. The source of select transistor ST1 is coupled to one end of a series of memory cell transistors MT0 to MT7. The other end of the series of memory cell transistors MT0 to MT7 is coupled to the drain of select transistor ST2.

The sources of select transistors ST2 in the same block BLK are coupled in common to a source line SL. The gates of select transistors ST1 in the string units SU0 to SU3 are coupled in common to respective select gate lines SGD0 to SGD3. The control gates of memory cell transistors MT0 to MT7 are coupled in common to word lines WL0 to WL7, respectively. The gates of select transistors ST2 are coupled in common to select gate line SGS.

In the above-described circuit configuration of the memory cell array 10, a plurality of NAND strings NS in different blocks BLK which are assigned with the same column address CA are coupled in common to the same bit line BL. The source line SL is shared by a plurality of blocks BLK.

A set of memory cell transistors MT coupled to a common word line WL in one string unit SU is referred to as, for example, a cell unit CU. For example, the storage capacity of the cell unit CU constituted by memory cell transistors MT configured to store 1-bit data is defined as “1-page data”. The cell unit CU may have a storage capacity of 2 or more-page data in accordance with the number of bits of data stored in each memory cell transistor MT.

The circuit configuration of the memory cell array 10 included in the semiconductor device 1 according to the embodiment is not limited to the above-described one. For example, the numbers of memory cell transistors MT, select transistors ST1, and select transistors ST2 in each NAND string NS may be any number. The number of string units SU included in each block BLK may be any number.

<1-1-3> Structure of Memory Cell Array 10

Hereinafter, an example of the structure of the memory cell array 10 in the embodiment will be described.

In the drawings to be referred to below, the X direction corresponds to the direction in which word lines WL extend. The Y direction corresponds to the direction in which bit lines BL extend. The Z direction corresponds to the direction perpendicular to the surface of a semiconductor substrate 20 on which the semiconductor device 1 is formed.

In the cross-sectional views to be referred to below, structural elements such as an insulating film (interlayer insulating film), an interconnect, and a contact are omitted as appropriate for easier understanding. The plan views include hatching as appropriate for easier understanding. The hatching added to the plan views does not necessarily relate to the material or characteristics of the hatched structural element.

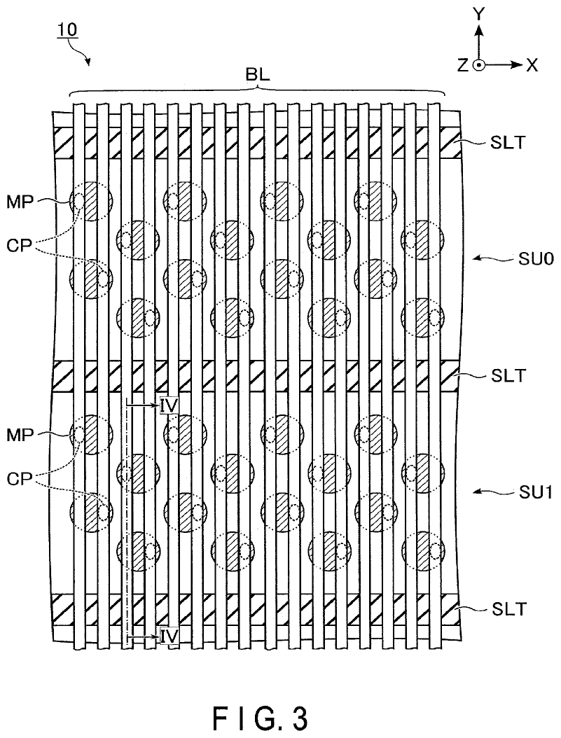

FIG. 3 is an example of the planar layout of the memory cell array 10 included in the semiconductor device 1 according to the embodiment, which shows structures corresponding to string units SU0 and SU′.

As shown in FIG. 3, the region where the memory cell array 10 is formed includes, for example, a plurality of slits SLT, a plurality of string units SU, and a plurality of bit lines BL.

The slits SLT extend in the X direction, and are aligned in the Y direction. For example, one string unit SU is disposed between slits SLT adjacent to each other in the Y direction.

Each string unit SU includes a plurality of memory pillars MP. The memory pillars MP are arranged, for example, in a zigzag in the X direction. Each memory pillar MP functions as, for example, one NAND string NS.

The bit lines BL extend in the Y direction, and are aligned in the X direction. For example, each bit line BL is disposed to overlap at least one memory pillar MP in each string unit SU. Specifically, two bit lines BL overlap each memory pillar MP, for example.

A contact CP is provided between a memory pillar MP and one of the bit lines BL overlapping the memory pillar MP. Each memory pillar MP is electrically coupled to the corresponding bit line BL via a contact CP.

The number of string units SU provided between adjacent slits SLT may be any number. The number and arrangement of memory pillars MP shown in FIG. 3 are mere examples, and may be determined at will. The number of bit lines BL overlapping each memory pillar MP may be any number.

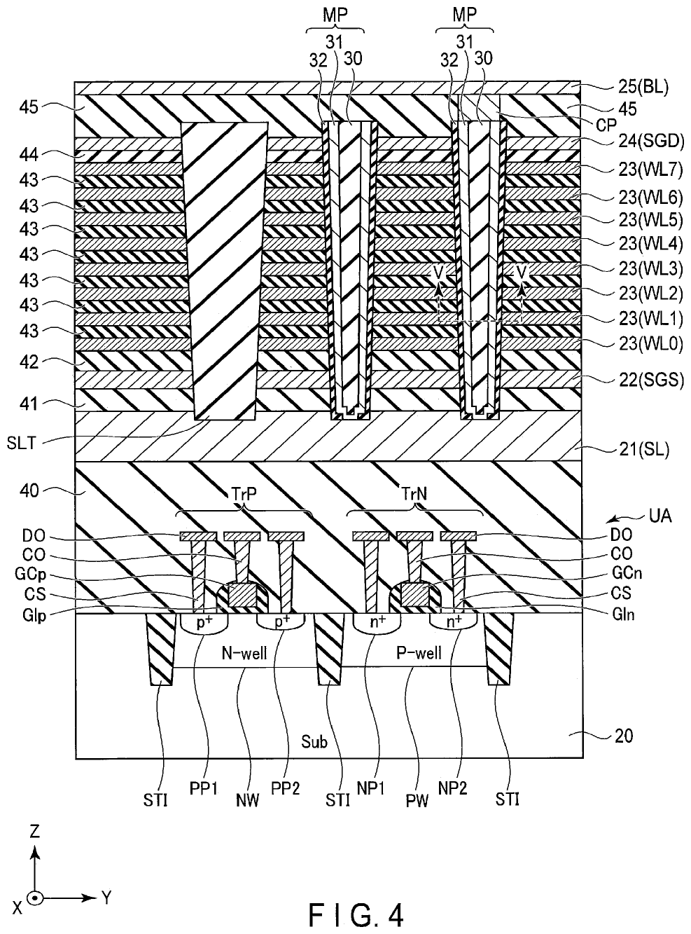

FIG. 4 is a cross-sectional view taken along line IV-IV in FIG. 3, which shows an example of the cross-section structure of the memory cell array 10 included in the semiconductor device 1 according to the embodiment.

As shown in FIG. 4, the region where the memory cell array 10 is formed includes, for example, conductor layers 21 to 25, a memory pillar MP, a contact CP, and a slit SLT.

Specifically, a circuit region UA is provided on the semiconductor substrate 20. In the circuit region UA, a circuit such as the sense amplifier module 16 is provided. The circuit includes, for example, an NMOS transistor TrN and a PMOS transistor TrP. The NMOS transistor TrN and PMOS transistor TrP herein are very low voltage transistors intended for a high-speed operation.

A conductor layer 21 is provided on the circuit region UA. For example, the conductor layer 21 has a plate-like shape expanding on an X-Y plane, and is used as the source line SL. The conductor layer 21 includes, for example, silicon (Si).

Above the conductor layer 21, a conductor layer 22 is provided with an insulating film interposed therebetween. For example, the conductor layer 22 has, for example, a plate-like shape expanding on an X-Y plane, and is used as select gate line SGS. The conductor layer 22 includes, for example, silicon (Si).

Above the conductor layer 22, an insulating film and a conductor layer 23 are alternately stacked. For example, the conductor layer 23 has a plate-like shape expanding on an X-Y plane. A plurality of stacked conductor layers 23 are used as word lines WL0 to WL7 in order from the semiconductor substrate 20's side. The conductor layers 23 include, for example, tungsten (W).

Above the topmost conductor layer 23, a conductor layer 24 is provided with an insulating film interposed therebetween. The conductor layer 24 has, for example, a plate-like shape expanding on an X-Y plane, and is used as select gate line SGD. The conductor layer 24 includes, for example, tungsten (W).

Above the conductor layer 24, a conductor layer 25 is provided with an insulating film interposed therebetween. For example, the conductor layer 25 has a linear shape extending in the Y direction, and is used as a bit line BL. In a region not shown, a plurality of conductor layers 25 are aligned in the X direction. The conductor layer 25 includes, for example, copper (Cu).

The memory pillar MP has a columnar shape extending in the Z direction, and passes through, for example, conductor layers 22 to 24. Specifically, the upper end of the memory pillar MP is included in, for example, a layer between the layer in which conductor layer 24 is provided and the layer in which conductor layer 25 is provided. The lower end of the memory pillar MP is included in, for example, the layer in which conductor layer 21 is provided.

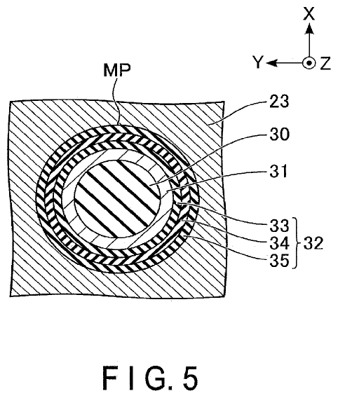

As shown in FIG. 5, the memory pillar MP includes, for example, a core member 30, a semiconductor layer 31, and a laminated film 32.

The core member 30 has a columnar shape extending in the Z-direction. The upper end of the core member 30 is included in, for example, a layer above the layer in which conductor layer 24 is provided. The lower end of the core member 30 is included in, for example, the layer in which conductor layer 21 is provided. The core member 30 includes an insulator, such as silicon oxide (SiO₂).

The core member 30 is covered with the semiconductor layer 31. The semiconductor layers 31 is, for example, polysilicon (Si). The laminated film 32 covers the side and bottom surfaces of the semiconductor layer 31 except for the portion of the semiconductor layer 31 in contact with conductor layer 21.

In a layer including conductor layer 23, the core member 30 is provided in the middle of the memory pillar MP. The semiconductor layer 31 surrounds the side surface of the core member 30. The laminated film 32 surrounds the side surface of the semiconductor layer 31. The laminated film 32 includes, for example, a tunnel insulating film 33, an insulating film 34, and a block insulating film 35.

The tunnel insulating film 33 surrounds the side surface of the semiconductor layer 31. The insulating film 34 surrounds the side surface of the tunnel insulating film 33. The block insulating film 35 surrounds the side surface of the insulating film 34. The conductor layer 23 surrounds the side surface of the block insulating film 35.

The tunnel insulating film 33 includes, for example, silicon oxide (SiO₂). The insulating film 34 includes, for example, silicon nitride (SiN). The block insulating film 35 includes, for example, silicon oxide (SiO₂).

Referring back to FIG. 4, a columnar contact CP is provided on the semiconductor layer 31. The region shown in the figure includes a contact CP corresponding to one memory pillar MP of the two memory pillars MP. A contact CP is coupled to the other memory pillar MP, which is not coupled to a contact CP in the region, in a region not shown in the figure.

The top surface of the contact CP is in contact with one conductor layer 25, i.e., one bit line BL. The memory pillar MP may be electrically coupled to the conductor layer 25 via two or more contacts, or another interconnect.

The slit SLT has a plate-like shape extending in the Z direction and splits, for example, conductor layers 22 to 24. Specifically, the upper end of the slit SLT is included in, for example, a layer between the layer including the upper end of the memory pillar MP and the layer in which conductor layer 25 is provided.

An insulator is provided in the slit SLT. The insulator includes, for example, silicon oxide (SiO₂). Multiple types of insulators may be provided in the slit SLT. For example, silicon nitride (SiN) may be formed as a side wall of the slit SLT before silicon oxide is filled in the slit SLT.

In the above-described structure of the memory pillar MP, for example, the portion where the memory pillar MP intersects conductor layer 22 functions as select transistor ST2. The portion where the memory pillar MP intersects conductor layer 23 functions as a memory cell transistor MT. The portion where the memory pillar MP intersects conductor layer 24 functions as select transistor ST1.

Namely, the semiconductor layer 31 is used as the channel of each of the memory cell transistors MT, and select transistors ST1 and ST2. The insulating film 34 is used as a charge storage layer of the memory cell transistor MT.

In the above-described structure of the memory cell array 10, the number of conductor layers 23 is designed based on the number of word lines WL. A plurality of conductor layers 24 may be assigned to select gate line SGD. A plurality of conductor layers 22 may be assigned to select gate line SGS. When there are multiple layers of select gate line SGS, a conductor different from conductor layer 22 may be used.

<1-1-4> Structures of NMOS Transistor TrN and PMOS Transistor TrP

Hereinafter, an example of the structure of each of the NMOS Transistor TrN and PMOS Transistor TrP in the embodiment will be described.

<1-1-4-1> Outline of Structure Under Memory Cell Array 10

First, an outline of the structure including the NMOS Transistor TrN and PMOS Transistor TrP provided under the memory cell array 10 will be described with continued reference to FIG. 4.

The semiconductor substrate 20 includes, for example, a P-type well region PW, an N-type well region NW, and an element isolation region STI. The circuit region UA includes, for example, conductors GC and D0, and contacts CS and C0.

The P-type well region PW, N-type well region NW, and element isolation region STI are each in contact with the top surface of the semiconductor substrate 20. The element isolation region STI insulates the N-type well region NW from the P-type well region PW.

The N-type well region NW, in which the PMOS transistor TrP is formed, includes p⁺-impurity diffusion regions PP1 and PP2 doped with, for example, boron (B). The p⁺-impurity diffusion regions PP1 and PP2 are provided apart from each other, and serve as the source (source diffusion layer) and drain (drain diffusion layer), respectively. The p⁺-impurity diffusion regions PP1 and PP2 are each in contact with the top surface of the semiconductor substrate 20.

The P-type well region PW, in which the NMOS transistor TrN is formed, includes n⁺-impurity diffusion regions NP1 and NP2 doped with, for example, phosphorus (P). The n⁺-impurity diffusion regions NP1 and NP2 are provided apart from each other, and serve as the source (source diffusion layer) and drain (drain diffusion layer), respectively. The n⁺-impurity diffusion regions NP1 and NP2 are each in contact with the top surface of the semiconductor substrate 20.

Conductor GCp is a gate electrode provided above the N-type well region NW between the p⁺-impurity diffusion regions PP1 and PP2. Conductor GCn is a gate electrode provided above the P-type well region PW between the n⁺-impurity diffusion regions NP1 and NP2. Conductors D0 are interconnects provided in a layer above conductors GCp and GCn.

Contacts CS are columnar conductors provided between the semiconductor substrate 20 and conductors D0. Contacts C0 are columnar conductors provided between conductors GCp and GCn and respective conductors D0.

The p⁺-impurity diffusion regions PP1 and PP2 and n⁺-impurity diffusion regions NP1 and NP2 are electrically coupled to different conductors D0 via respective contacts CS. Conductors GCp and GCn are electrically coupled to different conductors D0 via respective contacts C0.

As described above, the PMOS transistor TrP is formed in the N-type well region NW, and the NMOS transistor TrN is formed in the P-type well region PW.

<1-1-4-2> Structure of PMOS Transistor TrP

Next, an example structure of the PMOS transistor TrP will be described in more detail.

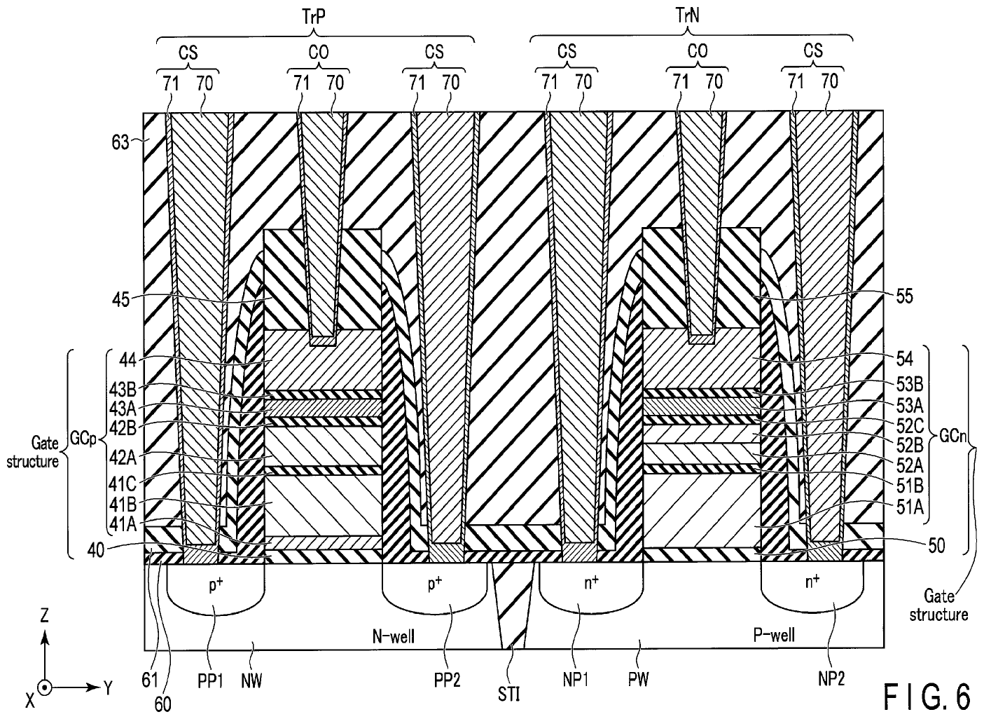

FIG. 6 shows an example of the cross-section structure of the PMOS transistor TrP provided under the memory cell array 10 in the semiconductor device 1 according to the embodiment.

As shown in FIG. 6, the region of the PMOS transistor TrP includes the N-type well region NW, the p⁺-impurity diffusion regions PP1 and PP2, conductor GCp, contacts CS and C0, and insulating films 40, 45, 60, 61, and 62.

Specifically, insulating film 40 is provided on the N-type well region NW between the p⁺-impurity diffusion regions PP1 and PP2. Insulating film 40 includes a laminated structure of, for example, silicon oxide (SiO₂) and silicon nitride (SiN), and serves as a gate insulating film of the PMOS transistor TrP.

Conductor GCp and insulating film 45 are stacked on insulating film 40 in order.

Conductor GCp is a laminated structure in which semiconductor layers 41A and 41B, insulating film 41C, semiconductor layer 42A, insulating film 42B, semiconductor layer 43A, insulating film 43B, and conductor layer 44 are stacked in order, and serves as the gate electrode (conductor GCp) of the PMOS transistor TrP. Semiconductor layer 41B is a polysilicon layer doped with boron (B). Semiconductor layer 41A is a polysilicon layer doped with boron (B) and carbon (C), and is used as a buffer layer that suppresses diffusion of boron (B) included in semiconductor layer 41B into the N-type well region NW. In this case, the concentration of boron (B) in semiconductor layer 41A is higher than that in semiconductor layer 41B. Insulating film 41C is, for example, silicon oxide (SiO₂). Insulating film 41C has such a film thickness as not to impair conductivity between the upper and lower films. Semiconductor layer 42A is a non-doped (impurity-free) polysilicon layer having a film thickness of about 35 to 40 nm. Semiconductor layer 42A may not be non-doped, and may include an impurity with an impurity concentration lower than that of semiconductor layer 41A. Insulating film 42B is, for example, silicon oxide (SiO₂), and is used as a diffusion prevention layer that suppresses diffusion of boron (B) included in semiconductor layer 43A to be described later into the lower non-doped semiconductor layer 42A. Insulating film 42B has such a film thickness as not to impair conductivity between the upper and lower films. Semiconductor layer 43A is a polysilicon layer having a film thickness of about 5 to 10 nm and doped with at least boron (B). Semiconductor layer 43A may be doped with carbon (C). The boron concentration of semiconductor layer 43A is the 21st power of a number, and that of semiconductor layer 41B is the 20th power of a number. Implantation of carbon (C) produces a certain effect in suppressing diffusion of boron (B); however, combination with the above-described insulating film 42B can enhance the effect of suppressing diffusion of boron (B). Insulating film 43B is, for example, silicon oxide (SiO₂), and is used as a layer that suppresses diffusion of boron (B) included in semiconductor layer 43A into conductor layer 44. Insulating film 43B has such a film thickness as not to impair conductivity between the upper and lower films. Conductor layer 44 includes, for example, a conductor layer.

Insulating film 45 is, for example, used as an etching stopper when a contact hole to the gate electrode is formed in a later step, and includes, for example, silicon nitride (SiN).

In the following description, the laminated structure of insulating film 40, semiconductor layers 41A and 41B, insulating film 41C, semiconductor layer 42A, insulating film 42B, semiconductor layer 43A, insulating film 43B, and conductor layer 44 may be referred to as a stacked gate structure.

On the side surface of the stacked gate structure, insulating films 60 and 61 are provided in order. Insulating films 60 and 61 are used as a side wall of the gate electrode of the PMOS transistor TrP. Insulating films 60 and 61 are also provided on the top surface of the N-type well region NW. Insulating film 62 is provided to cover insulating film 61.

In the above-described structure relating to the PMOS transistor TrP, contact C0 is formed in a contact hole that passes through insulating film 62 and insulating film 45, and the bottom of the contact C0 is in contact with conductor layer 44.

Contact CS is formed in a contact hole that passes through insulating films 62, 61, and 60, and the bottom of the contact CS is in contact with p⁺-impurity diffusion region PP1 or PP2.

Contact CS includes, for example, conductors 70 and 71. Conductor 71 includes a portion provided on p⁺-impurity diffusion region PP1 or PP2 and a cylindrical portion extending therefrom. In other words, conductor 71 is provided on the inner wall and bottom surface of the contact hole having a bottom in contact with p⁺-impurity diffusion region PP1 or PP2, and is in contact with p⁺-impurity diffusion region PP1 or PP2. Conductor 71 includes, for example, titanium nitride (TiN), and is used as a barrier metal in manufacturing steps of the semiconductor device 1. Conductor 70 is, for example, filled inside of conductor 71. Conductor 70 includes, for example, tungsten (W).

The detailed structure of contact CS corresponding to the PMOS transistor TrP applies to contacts CS and C0 corresponding to the NMOS transistor TrN and contact C0 corresponding to the PMOS transistor TrP.

<1-1-4-3> Structure of NMOS Transistor TrN

Next, an example structure of the NMOS transistor TrN will be described in more detail.

FIG. 6 shows an example of the cross-section structure of the NMOS transistor TrN provided under the memory cell array 10 in the semiconductor device 1 according to the embodiment.

As shown in FIG. 6, the region of the NMOS transistor TrN includes the P-type well region PW, the n⁺-impurity diffusion regions NP1 and NP2, conductor GCn, contacts CS and C0, and insulating films 50, 55, 60, 61, and 62.

Specifically, insulating film 50 is provided on the P-type well region PW between the n⁺-impurity diffusion regions NP1 and NP2. Insulating film 50 includes a laminated structure of, for example, silicon oxide (SiO₂) and silicon nitride (SiN), and serves as a gate insulating film of the NMOS transistor TrN.

Conductor GCn and insulating film 55 are stacked on insulating film 50 in order.

Conductor GCn is a laminated structure in which semiconductor layer 51A, insulating film 51B, semiconductor layers 52A and 52B, insulating film 52C, semiconductor layer 53A, insulating film 53B, and conductor layer 54 are stacked in order, and serves as the gate electrode (conductor GCn) of the NMOS transistor TrN. Semiconductor layer 51A is a phosphorus (P)-doped polysilicon layer. Insulating film 51B is, for example, silicon oxide (SiO₂). Insulating film 51B has such a film thickness as not to impair conductivity between the upper and lower films. Semiconductor layer 52A is a non-doped polysilicon layer. Semiconductor layer 52B is a phosphorus-doped polysilicon layer. The film thickness of each of semiconductor layers 52A and 52B is, for example, about 35 to 40 nm. Insulating film 52C is, for example, silicon oxide (SiO₂), and is used as a diffusion prevention layer that suppresses diffusion of phosphorus (P) included in semiconductor layer 52B to be described later into the non-doped semiconductor layer 53A. Insulating film 52C has such a film thickness as not to impair conductivity between the upper and lower films. Semiconductor layer 53A is a polysilicon layer having a film thickness of about 5 to 10 nm and doped with carbon (C). Insulating film 53B is, for example, silicon oxide (SiO₂), and is used as a diffusion prevention layer that suppresses diffusion of phosphorus (P) into conductor layer 54. Insulating film 53B has such a film thickness as not to impair conductivity between the upper and lower films. Conductor layer 54 includes, for example, tungsten silicide (WSi).

Insulating film 55 is, for example, used as an etching stopper when a contact hole to the gate electrode is formed in a later step, and includes, for example, silicon nitride (SiN).

In the following description, the laminated structure of insulating film 50, semiconductor layer 51A, insulating film 51B, semiconductor layers 52A and 52B, insulating film 52C, semiconductor layer 53A, insulating film 53B, and conductor layer 54 may be referred to as a stacked gate structure.

The stacked gate structure in the PMOS transistor TrP and the stacked gate structure in the NMOS transistor TrN have the same Z-direction height from the surface of the semiconductor substrate.

On the side surface of the stacked gate structure, insulating films 60 and 61 are provided in order. Insulating films 60 and 61 are used as a side wall of the gate electrode of the NMOS transistor TrN. Insulating films 60 and 61 are also provided on the top surface of the P-type well region PW. Insulating film 62 is provided to cover insulating film 61.

In the above-described structure relating to the NMOS transistor TrN, contact C0 is formed in the contact hole that passes through insulating film 62 and insulating film 55, and the bottom of the contact C0 is in contact with conductor layer 54.

Contact CS is formed in the contact hole that passes through insulating films 62, 61, and 60, and the bottom of the contact CS is in contact with n⁺-impurity diffusion region NP1 or NP2.

<1-2> Method for Manufacturing Semiconductor Device 1

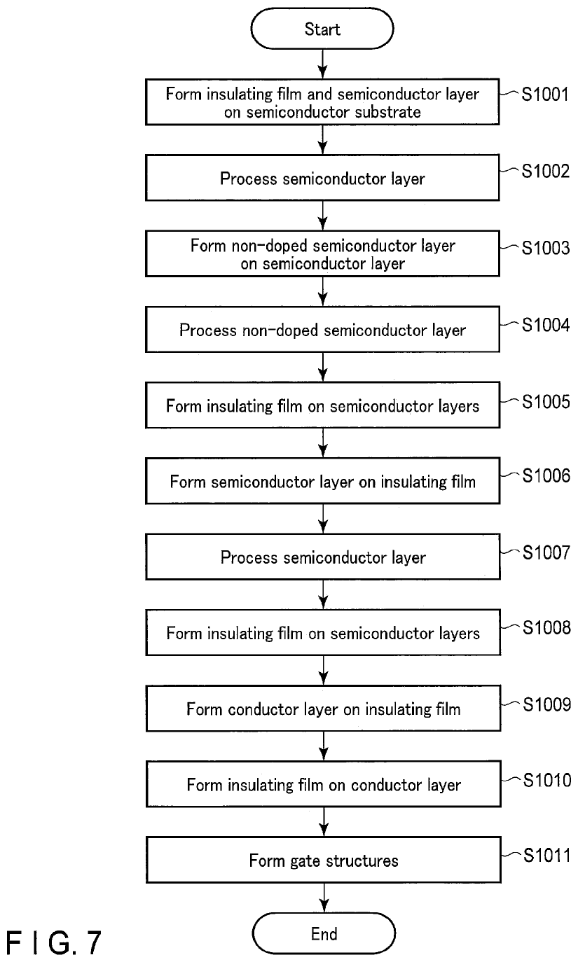

Hereinafter, an example of the manufacturing steps for forming the NMOS Transistor TrN and PMOS Transistor TrP in the embodiment will be described with reference to FIGS. 7 to 18.

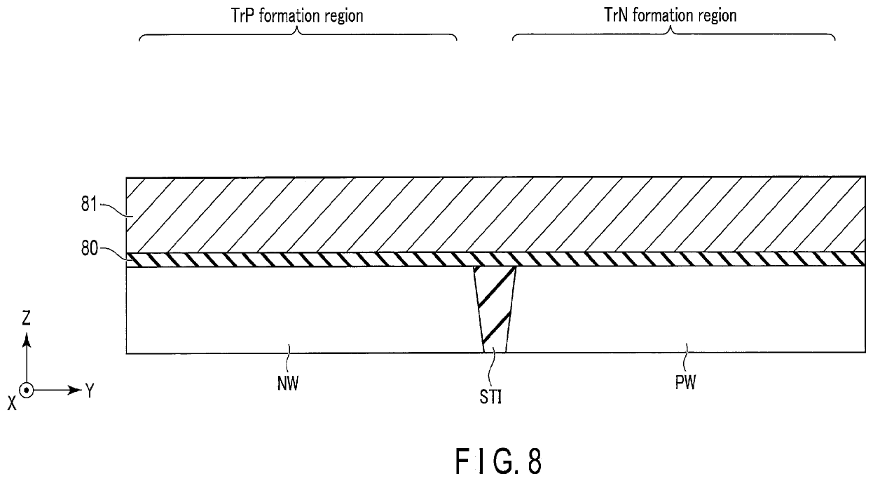

FIG. 7 is a flowchart showing an example of the method for manufacturing the semiconductor device 1 according to the embodiment. FIGS. 8 to 18 show examples of cross-section structures including structures corresponding to the PMOS transistor TrP formation region and the NMOS transistor TrN formation region in respective manufacturing steps of the semiconductor device 1 according to the embodiment. Detailed description of the memory cell array 10 provided above the circuit region UA will be omitted.

[Step S1001]

First, insulating film 80 and semiconductor layer 81 are formed above a semiconductor substrate. Specifically, as shown in FIG. 8, insulating film 80 having a laminated structure of a silicon insulating film and a silicon nitride film is formed on a P-type well region PW, N-type well region NW, and element isolation region STI, and polysilicon, which serves as semiconductor layer 81, is further formed on the insulating film 80.

[Step S1002]

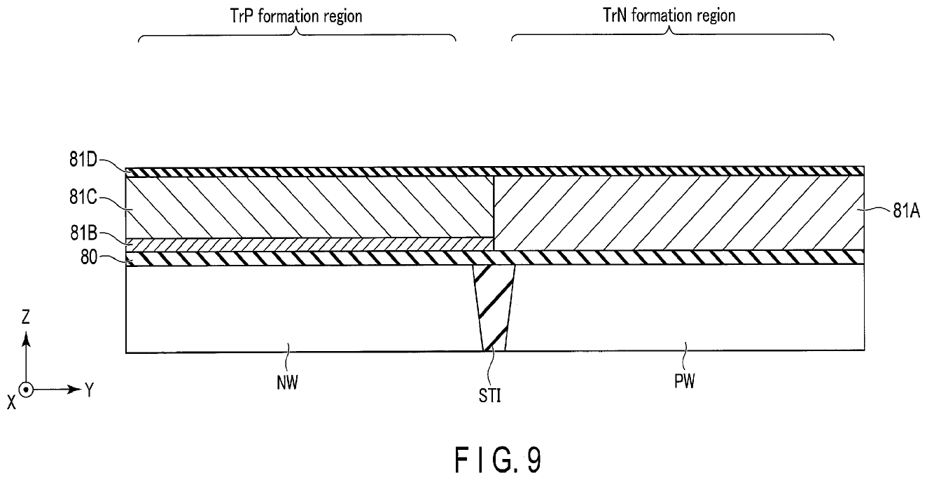

Next, as shown in FIG. 9, by, for example, covering the PMOS transistor TrP formation region with a mask or the like, semiconductor layer 81 in the NMOS transistor TrN formation region is doped with phosphorus (P) to form semiconductor layer 81A. Next, by, for example, covering the NMOS transistor TrN formation region with a mask or the like, semiconductor layer 81 in the PMOS transistor TrP formation region is doped with carbon (C) to form semiconductor layer 81B, and then doped with boron (B) with energy smaller than that for implantation of carbon (C) to form semiconductor layer 81C. Then, a natural oxide film (insulating film 81D) of about several nm is formed on the surfaces of semiconductor layers 81A and 81C by heat in manufacture.

[Step S1003]

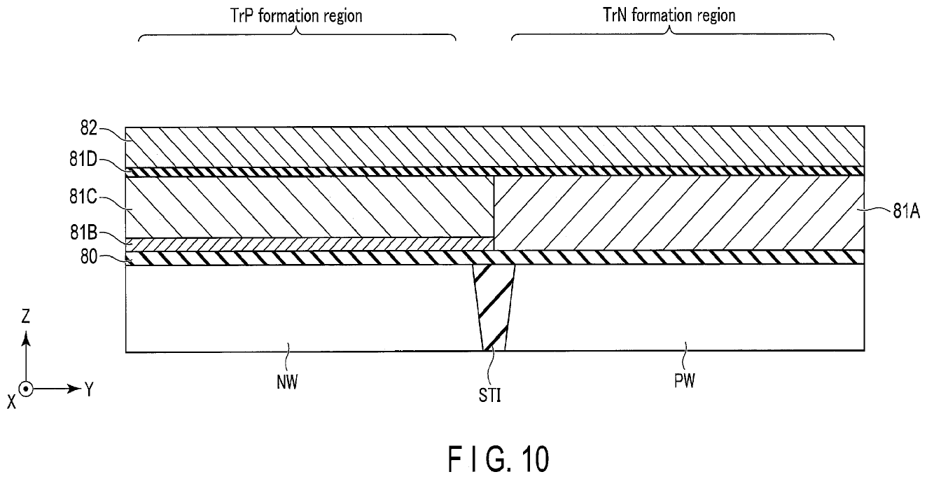

Next, as shown in FIG. 10, non-doped polysilicon having a film thickness of about 35 to 40 nm is formed on insulating film 81D as semiconductor layer 82.

[Step S1004]

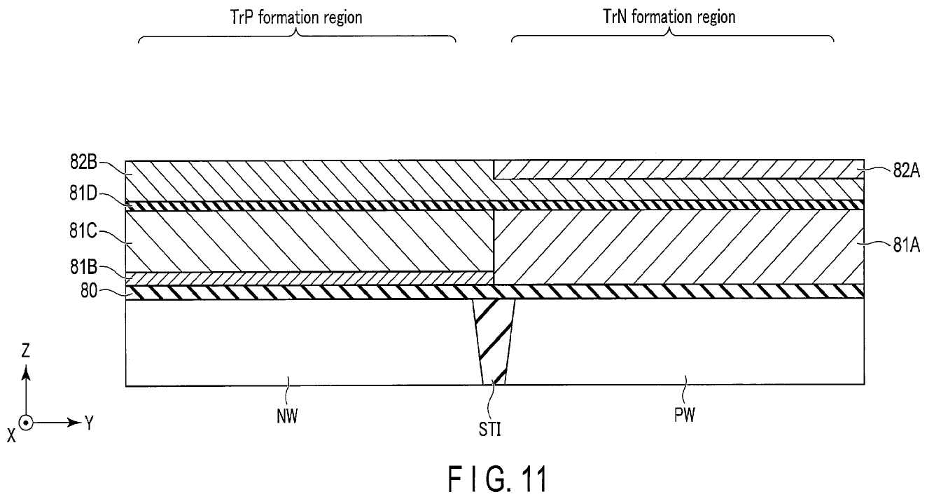

Next, as shown in FIG. 11, by, for example, covering the region of semiconductor layer 82 on the PMOS transistor TrP side with a mask (not shown) or the like, phosphorus (P) is selectively implanted by, for example, ion implantation, into the region of semiconductor layer 82 on the NMOS transistor TrN side, thereby forming N-type semiconductor layer 82A. The remaining region of semiconductor layer 82, where N-type semiconductor layer 82A is not formed, is a non-doped polysilicon layer, and will be referred to as semiconductor layer 82B, herein.

[Step S1005]

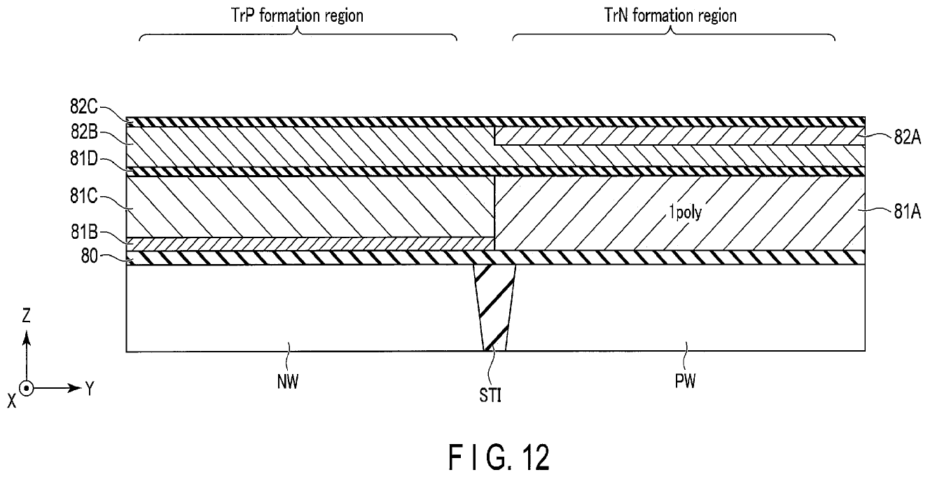

Next, as shown in FIG. 12, insulating film 82C is formed on the surfaces of semiconductor layers 82B and 82A. Insulating film 82C may be formed by thermal oxidation, or may be a natural oxide film or the like having a film thickness of about a few nm.

[Step S1006]

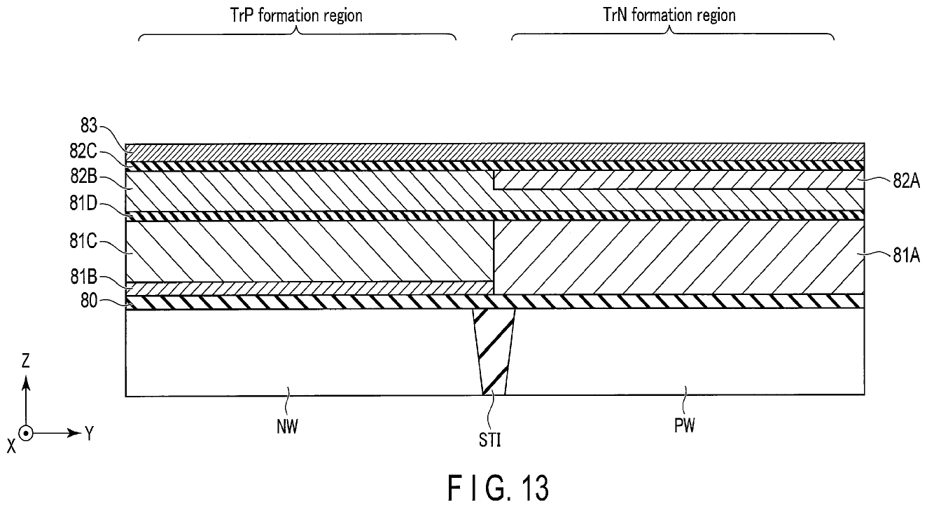

Next, as shown in FIG. 13, carbon (C)-doped polysilicon having a film thickness of about 5 to 10 nm is formed on insulating film 82C as semiconductor layer 83.

[Step S1007]

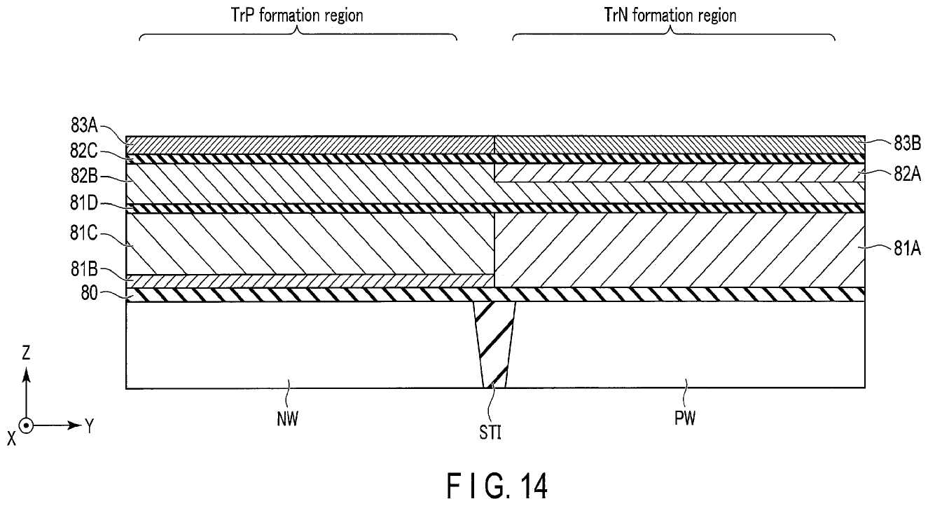

Next, as shown in FIG. 14, by, for example, covering the NMOS transistor TrN formation region with a mask (not shown) or the like, boron (B) is implanted into semiconductor layer 83 in the PMOS transistor TrP formation region, thereby forming semiconductor layer 83A. The portion of semiconductor layer 83 other than semiconductor layer 83A will be referred to as semiconductor layer 83B.

[Step S1008]

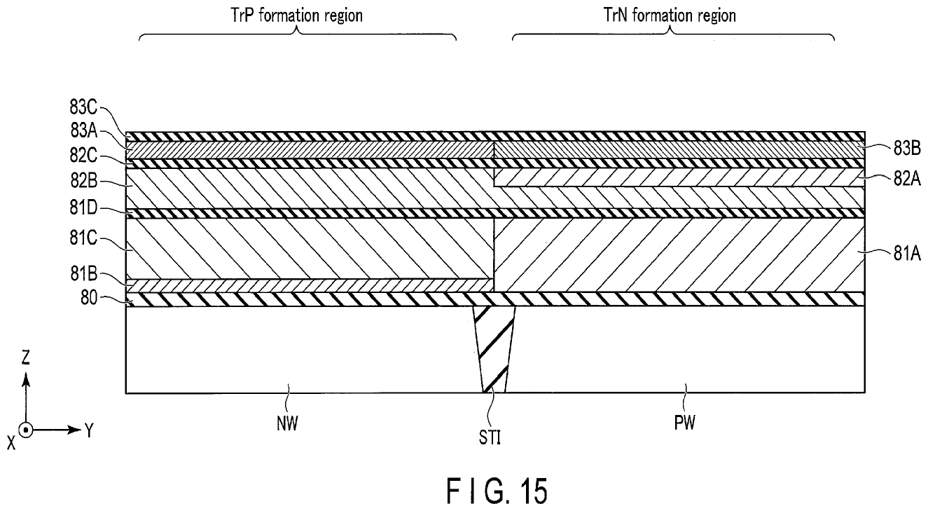

Next, as shown in FIG. 15, insulating film 83C is formed on the surfaces of semiconductor layers 83A and 83B by heat treatment such as thermal oxidation. Insulating film 83C may be a natural oxide film or the like having a film thickness of about a few nm. Insulating film 82C is provided between semiconductor layers 82B and 83A and between semiconductor layers 82A and 83B. Therefore, as shown in FIG. 15, when the heat treatment is performed, diffusion of boron (B) from semiconductor layer 83A to non-doped semiconductor layer 82B can be suppressed, and reduction of the boron (B) concentration of semiconductor layer 83A can be suppressed. In addition, insulating film 82C suppresses diffusion of phosphorus (P) from semiconductor layer 82A to semiconductor layer 83B.

The oxidation rate of insulating film 83C formed on semiconductor layer 83B is associated with the concentration of phosphorus (P) in semiconductor layer 83B. For example, the oxidation rate of insulating film 83C on semiconductor layer 83B including phosphorus (P) is higher than the oxidation rate of insulating film 83C on semiconductor layer 83A not including phosphorus (P). As a result, the film thickness of insulating film 83C formed on semiconductor layer 83B becomes larger than the film thickness of insulating film 83C formed on semiconductor layer 83A. Increase in the insulating film thickness causes increase in the resistance (also referred to as EI resistance) of the contact for coupling with the upper conductive layer (not shown), and consequently causes deterioration in the transistor operation. In particular, when the transistor is a low-voltage N-type transistor or P-type transistor, the transistor may not operate at high speed.

In addition, if boron (B) diffuses into the well, such as the N-type well NW, where the source and drain of the transistor are formed, the threshold of the transistor may fall outside a desired range, or cause variation of the transistor characteristics.

Therefore, if the transistor is that for memory control, the performance of the memory operation may be impaired.

According to the present embodiment, insulating film 82C can suppress diffusion of phosphorus (P) into semiconductor layer 83B; therefore, the oxidation speed of the insulating film formed on semiconductor layer 83B can be controlled, and the above-described deterioration of the transistor operation and impairment of the memory performance can be suppressed.

According to this embodiment, the film thickness of the insulating film formed on semiconductor layer 83B is approximately the same as the film thickness of the insulating film formed on semiconductor layer 83A.

[Step S1009]

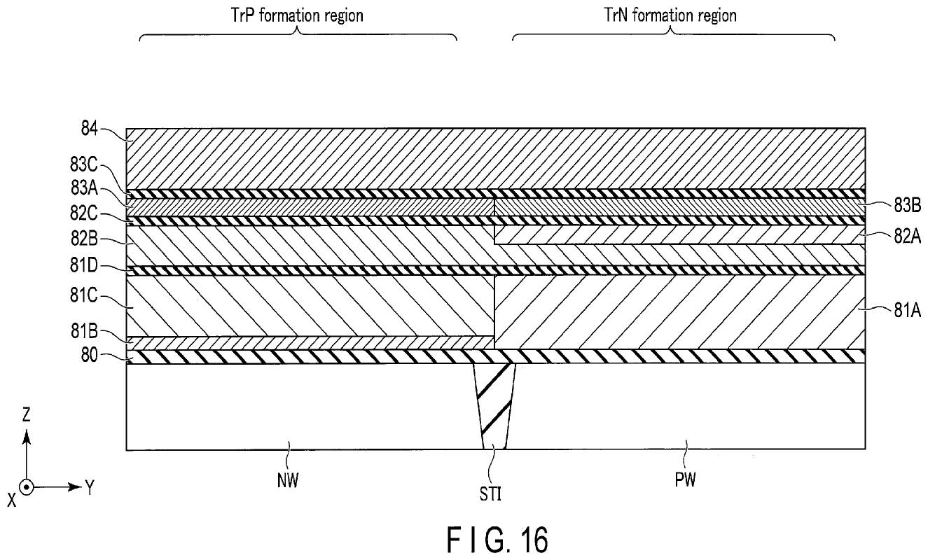

Next, conductor layer 84 is formed. Specifically, as shown in FIG. 16, tungsten silicide (WSi) is formed on insulating film 83C as conductor layer 84. As shown in FIG. 16, insulating film 83C is provided between semiconductor layer 83A and conductor layer 84 and between semiconductor layer 83B and conductor layer 84. Therefore, diffusion of boron (B) implanted into semiconductor layer 83A into conductor layer 84 can be suppressed. Consequently, decrease in the concentration of boron (B) in semiconductor layer 83A can be suppressed. Accordingly, deterioration in resistance between semiconductor layer 83A and conductor layer 84 can be suppressed.

[Step S1010]

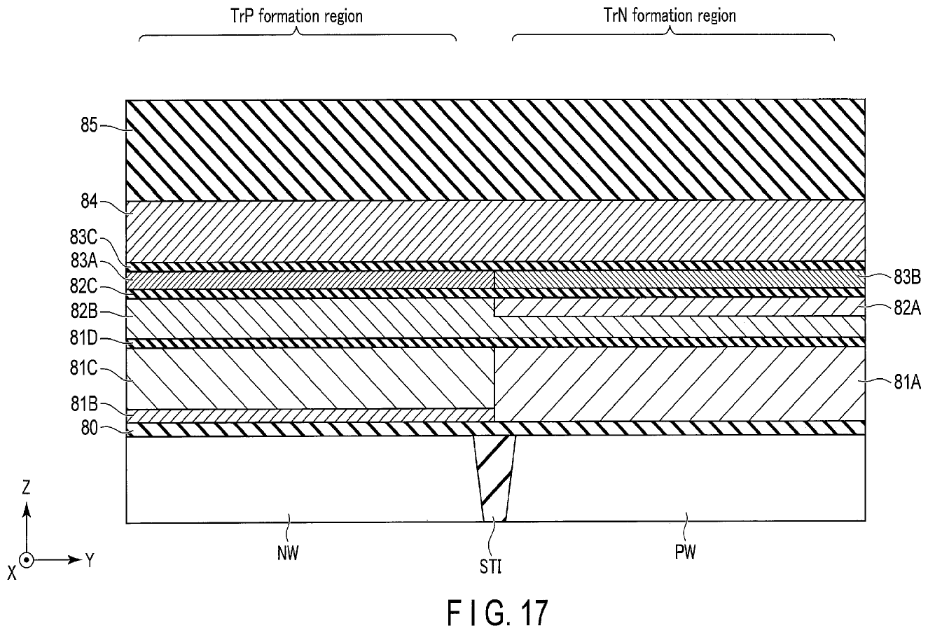

Next, insulating film 85 is formed. Specifically, as shown in FIG. 17, silicon nitride (SiN) is formed on conductor layer 84 as insulating film 85. This silicon nitride (SiN) is used as an etching stopper. The temperature to form silicon nitride (SiN) is high; however, as described with reference to FIGS. 15 and 16, thanks to insulating films 82C and 83C, the above-described advantage can be attained even though the heat treatment is performed.

[Step S1011]

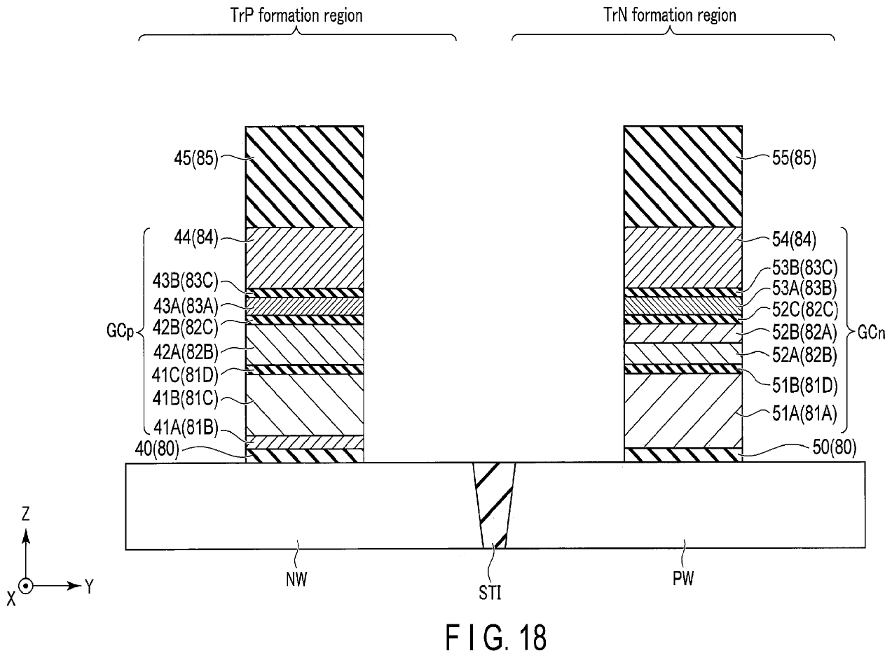

Next, gate structures are formed. Specifically, as shown in FIG. 18, the laminated structure is processed into the gate structure of the PMOS transistor TrP and the gate structure of the NMOS transistor TrN by performing anisotropic etching, such as reactive ion etching (RIE) using a mask (not shown).

Accordingly, in the PMOS transistor TrP formation region, insulating film 80 changes to insulating film 40. In addition, semiconductor layer 81B changes to semiconductor layer 41A, semiconductor layer 81C changes to semiconductor layer 41B, and insulating film 81D changes into insulating film 41C. Furthermore, semiconductor layer 82B changes to semiconductor layer 42A, and insulating film 82C changes to insulating film 42B. Moreover, semiconductor layer 83A changes to semiconductor layer 43A, and insulating film 83C changes to insulating film 43B. Conductor layer 84 changes to conductor layer 44, and insulating film 85 changes to insulating film 45.

In the NMOS transistor TrN formation region, insulating film 80 changes to insulating film 50. Similarly, semiconductor layer 81A changes to semiconductor layer 51A, and insulating film 81D changes to insulating film 51B. Semiconductor layer 82B changes to semiconductor layer 52A, semiconductor layer 82A changes to semiconductor layer 52B, and insulating film 82C changes to insulating film 52C. Semiconductor layer 83B changes to semiconductor layer 53A, and insulating film 83C changes to insulating film 53B. Conductor layer 84 changes to conductor layer 54, and insulating film 85 changes to insulating film 55.

After that, the PMOS transistor TrP and NMOS transistor TrN shown in FIG. 4 are formed through predetermined steps. Then, the memory cell array 10 is formed through predetermined steps.

As described with reference to FIGS. 15 and 16, thanks to insulating films 82C and 83C, the above-described advantage can be attained even though the heat treatment in the manufacturing steps from step S1010 onward is performed.

<1-3> Advantage

According to the above-described embodiment, in manufacturing steps to form the PMOS transistor TrP and NMOS transistor TrN, insulating film 82C is provided between semiconductor layers 82B and 82A and between semiconductor layers 83A and 83B, and insulating film 83C is provided between conductor layer 84 and each of semiconductor layers 83A and 83B.

Accordingly, even though heat treatment is performed in the manufacturing process of the semiconductor device, deterioration in the transistor characteristics of the PMOS transistor TrP and NMOS transistor TrN can be suppressed.

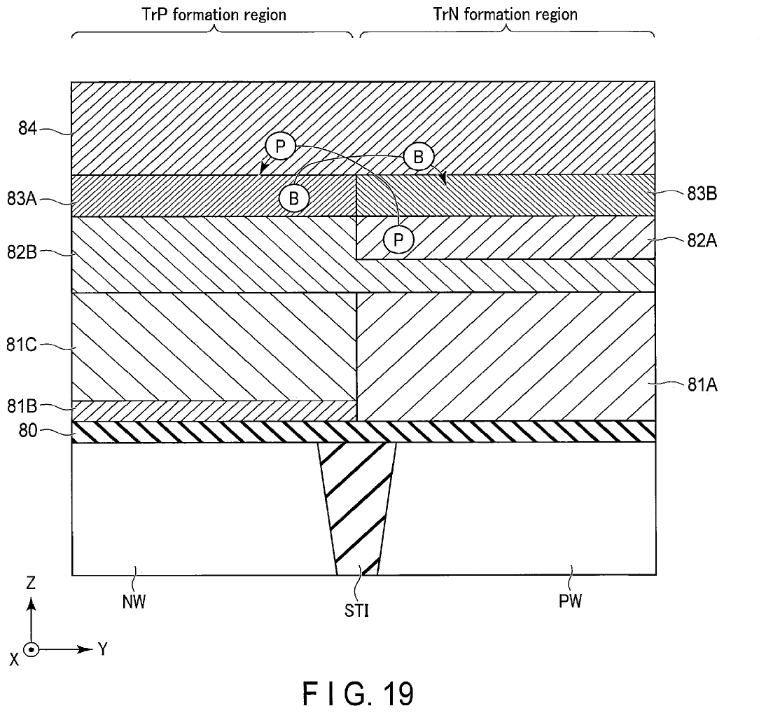

To explain the advantage of the above-described embodiment, a comparative example will be described with reference to FIGS. 19 to 21.

A comparative example, in which semiconductor layer 81B, and insulating films 81D, 82C, and 83C are not provided as shown in FIG. 19, and semiconductor layers 83A and 83B do not include carbon (C), will be described. When insulating film 83C is not provided, boron (B) included in semiconductor layer 83A is diffused into conductor layer 84, etc. by heat treatment, and the concentration of boron (B) included in semiconductor layer 83A decreases. Moreover, due to interdiffusion to be described later, phosphorus (P) may diffuse into a region including boron (B), and boron (B) may diffuse into a region including phosphorus (P). This causes a problem that the resistance at the interface between semiconductor layer 83A and conductor layer 84 increases. The interdiffusion is diffusion of boron (B) included in semiconductor layer 83A via conductor layer 84 into semiconductor layer 83B and diffusion of phosphorus (P) included in semiconductor layer 83B via conductor layer 84 into semiconductor layer 83A.

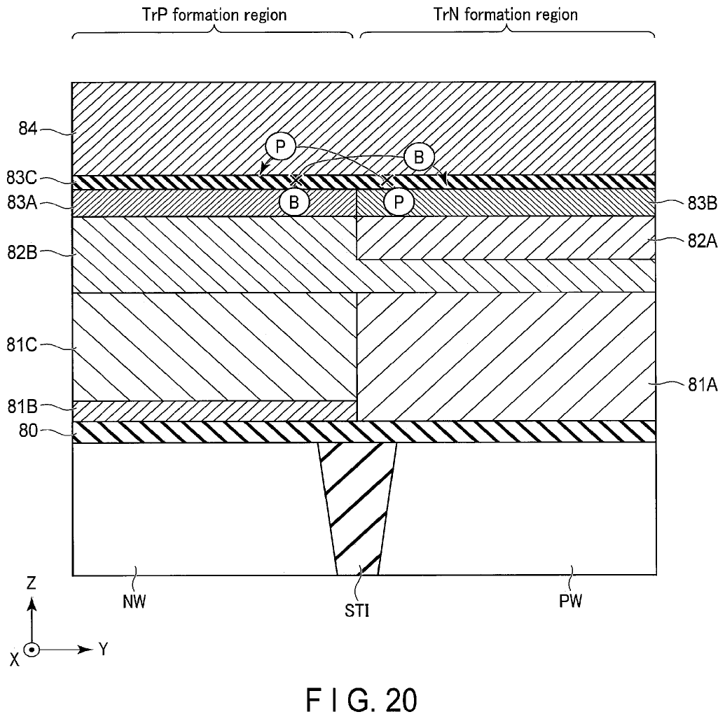

As shown in FIG. 20, by providing an insulating film between conductor layer 84 and each of semiconductor layers 83A and 83B, the above-described interdiffusion can be suppressed.

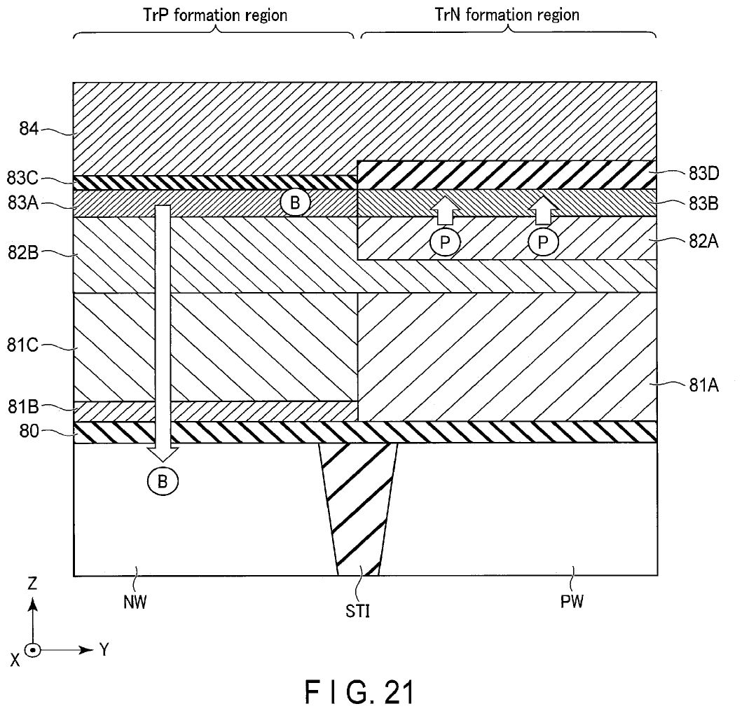

In this case, however, as shown in FIG. 21, boron (B) included in semiconductor layer 83A may diffuse toward the N-type well region NW. This causes decrease in the concentration of boron (B) included in semiconductor layer 83A, and consequently causes a problem that the resistance at the interface between semiconductor layer 83A and conductor layer 84 increases. In addition, boron (B) included in semiconductor layer 83A may diffuse into the N-type well region NW; in this case, the threshold voltage of the PMOS transistor TrP varies.

As shown in FIG. 21, phosphorus (P) included in semiconductor layer 82A is also diffused into semiconductor layer 83B by heat treatment. This causes increase in the concentration of phosphorus (P) included in semiconductor layer 83B and may provide the insulating film produced at the interface between semiconductor layer 83B and conductor layer 84 with a film thickness larger than the film thickness of the insulating film produced at the interface between semiconductor layer 83A and conductor layer 84 due to enhanced oxidation by phosphorus (P). This causes a problem that the resistance at the interface between semiconductor layer 83B and conductor layer 84 in the NMOS transistor TrN increases.

The above-described diffusion of boron (B) and phosphorus (P) is caused by high-temperature heat treatment in manufacturing steps to form the memory cell. Namely, when the PMOS transistor TrP and NMOS transistor TrN are formed or when a high-temperature treatment such as thermal diffusion is performed thereafter in manufacturing steps to form a memory cell, the above-described problem of deterioration in the transistor operation or impairment of the memory performance may be prominent.

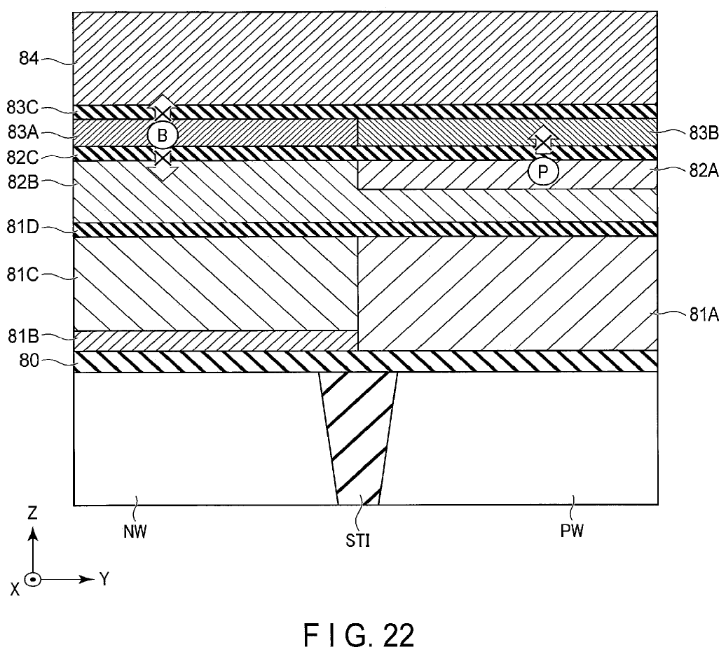

Unlike in the comparative example, as shown in FIG. 22, insulating film 82C is provided between semiconductor layers 82B and 82A and between semiconductor layers 83A and 83B in the present embodiment. Therefore, diffusion of boron (B) from semiconductor layer 83A into semiconductor layer 82B can be suppressed. In addition, diffusion of phosphorus (P) from semiconductor layer 82A into semiconductor layer 83B can be suppressed. Moreover, insulating film 83C is provided between conductor layer 84 and each of semiconductor layers 83A and 83B in the present embodiment. Therefore, diffusion of boron (B) from semiconductor layer 83A into conductor layer 84 can be suppressed.

This can suppress decrease in the concentration of boron (B) included in semiconductor layer 83A, and can suppress increase in the resistance at the interface between semiconductor layer 83A and conductor layer 84. In addition, diffusion of boron (B) included in semiconductor layer 83A into the N-type well region NW can also be suppressed.

Furthermore, diffusion of phosphorus (P) into semiconductor layer 83B can be suppressed. As a result, enhanced oxidation can be suppressed when insulating film 83C is formed. Therefore, the film thickness of insulating film 83C in the NMOS transistor TrN can be controlled, and the interface resistance between semiconductor layer 83B and conductor layer 84 can be reduced.

Moreover, as described in the above embodiment, semiconductor layer 81B including carbon (C) is provided between the N-type well region NW and semiconductor layer 81C. Carbon (C) included in semiconductor layer 81B suppresses diffusion of boron (B). Therefore, diffusion of boron (B) from semiconductor layer 81C to the N-type well region NW can be suppressed.

As described in the above embodiment, semiconductor layer 83A includes carbon(C). Therefore, diffusion of boron (B) in semiconductor layer 83A can be further suppressed.

As described above, the above-described embodiment can suppress the above-described diffusion of boron (B) and phosphorus (P) even if a semiconductor device is manufactured by a high-temperature heat treatment performed after a PMOS transistor TrP and NMOS transistor TrN are formed. As a result, the above-described embodiment can provide a high-quality PMOS transistor TrP and NMOS transistor TrN.

### <2> Other Modifications, Etc.

The manufacturing steps described in the above embodiment and modification are mere examples. Another step may be interposed between manufacturing steps, and the order of the manufacturing steps may be altered as appropriate. Any manufacturing steps of the semiconductor device 1 may be adopted as long as the structures described in the embodiment and modification can be formed.

In the above embodiment, the memory cell array 10 may have a different structure. For example, the memory pillar MP may have a structure in which a plurality of pillars are coupled in the Z direction. Alternatively, the memory pillar MP may have a structure in which a pillar passing through conductor layer 24 (select gate line SGD) is coupled with a pillar passing through a plurality of conductor layers 23 (word lines WL). Alternatively, the memory pillar MP may have a structure in which a plurality of pillars each passing through a plurality of conductor layers 23 are coupled in the Z direction.

In the above embodiment, the case where the semiconductor device 1 has a structure in which a circuit such as a sense amplifier module 16 is provided under the memory cell array 10 is described as an example; however, the structure is not limited to this. For example, the semiconductor device 1 may have a structure in which the memory cell array 10 is formed on the semiconductor substrate 20. In this case, semiconductor layer 31 is electrically coupled to the source line SL via, for example, the bottom of the memory pillar MP.

The “coupling” herein refers to electrical coupling, and does not exclude, for example, existence of another element between the coupled elements.

The “polysilicon” herein can be reworded as a polycrystalline semiconductor.

While an embodiment has been described, this embodiment has been presented as an example, and is not intended to limit the scope of the invention. This novel embodiment may be embodied in various forms, and various omissions, replacements, and changes can be made thereon without departing from the spirit of the invention. The embodiment and modifications are included in the scope and spirit of the invention and are included in the scope of the claimed inventions and their equivalents.

1. A semiconductor device comprising:
an N-type first well region;
a P-type source diffusion layer and drain diffusion layer provided on a top surface of the first well region;
a first gate insulating layer provided on the first well region between the P-type source diffusion layer and the P-type drain diffusion layer;
a P-type first semiconductor layer provided on the first gate insulating layer;
a second semiconductor layer provided on the first semiconductor layer via a first insulating layer;
a P-type third semiconductor layer provided on the second semiconductor layer via a second insulating layer and including boron; and
a first conductive layer provided on the third semiconductor layer via a third insulating layer.

2. The semiconductor device according to claim 1, further comprising:
a P-type second well region adjacent to the first well region via an element isolation film;
an N-type source diffusion layer and drain diffusion layer provided on a top surface of the second well region;
a second gate insulating layer provided on the second well region between the N-type source diffusion layer and the N-type drain diffusion layer;
an N-type fourth semiconductor layer provided on the second gate insulating layer;
a fifth semiconductor layer provided on the fourth semiconductor layer via a fourth insulating layer and including an upper layer including phosphorus (P) and a lower layer including no impurity;
a sixth semiconductor layer provided on the fifth semiconductor layer via a fifth insulating layer; and
a second conductive layer provided on the sixth semiconductor layer via a sixth insulating layer.

3. The semiconductor device according to claim 2, wherein a P-type MOSFET and an N-type MOSFET are provided on the first well region and the second well region, respectively.

4. The semiconductor device according to claim 3, further comprising:
a plurality of memory cell pillars each including a plurality of memory cells stacked on one another,
wherein the P-type MOSFET and N-type MOSFET constitute part of a peripheral circuit configured to control the memory cells.

5. The semiconductor device according to claim 2, wherein the second insulating layer and the fifth insulating layer are a natural oxide film.

6. The semiconductor device according to claim 2, wherein the third insulating layer and the sixth insulating layer are a natural oxide film.

7. The semiconductor device according to claim 1, wherein the third semiconductor layer further includes carbon.

8. The semiconductor device according to claim 1, wherein a region of the first semiconductor layer close to the first gate insulating layer includes carbon.

9. The semiconductor device according to claim 1, wherein the second semiconductor layer has an impurity concentration lower than an impurity concentration of the first semiconductor layer, or includes no impurity.

10. The semiconductor device according to claim 1, wherein
the first insulating layer has such a film thickness as not to impair conductivity between the first semiconductor layer and the second semiconductor layer,
the second insulating layer has such a film thickness as not to impair conductivity between the second semiconductor layer and the third semiconductor layer, and
the third insulating layer has such a film thickness as not to impair conductivity between the third semiconductor layer and the first semiconductor layer.

11. The semiconductor device according to claim 2, wherein a film thickness of the third insulating layer is equivalent to a film thickness of the sixth insulating layer.

12. A semiconductor memory device comprising:
a P-type first well region;
an N-type source diffusion layer and drain diffusion layer provided on a top surface of the first well region;
a first gate insulating layer provided on the first well region between the N-type source diffusion layer and the N-type drain diffusion layer;
an N-type first semiconductor layer provided on the first gate insulating layer;
a second semiconductor layer provided on the first semiconductor layer via a first insulating layer;
a third semiconductor layer provided on the second semiconductor layer via a second insulating layer and including phosphorus with a concentration higher than a concentration of phosphorus of the second semiconductor layer, and
a first conductive layer provided on the third semiconductor layer via a third insulating layer.

13. The semiconductor device according to claim 12, further comprising:
an N-type second well region;
a P-type source diffusion layer and drain diffusion layer provided on a top surface of the second well region;
a second gate insulating layer provided on the second well region between the P-type source diffusion layer and the P-type drain diffusion layer;
a P-type fourth semiconductor layer provided on the second gate insulating layer;
a fifth semiconductor layer provided on the fourth semiconductor layer via a fourth insulating layer;
a P-type sixth semiconductor layer provided on the fifth semiconductor layer via a fifth insulating layer and including boron; and
a second conductive layer provided on the sixth semiconductor layer via a sixth insulating layer.

14. The semiconductor device according to claim 12, wherein the second semiconductor layer includes an upper layer including phosphorus with a concentration lower than the concentration of phosphorus of the second semiconductor layer.

15. The semiconductor device according to claim 12, wherein a region of the first semiconductor layer close to the first gate insulating layer includes carbon (C).

16. The semiconductor device according to claim 12, wherein the third semiconductor layer further includes carbon.

17. The semiconductor device according to claim 13, wherein a film thickness of the third insulating layer is equivalent to a film thickness of the sixth insulating layer.
